(19) United States
(12) Patent Application Publication
(10) Pub. No.: US 2004/0224524 A1
(43) Pub. Date: Nov. 11, 2004

(54) Maintaining the dimensions of features being etched on a lithographic mask

(75) Inventors: Alfred Wolfgang Koenig, Mintraching (DE); Henry Christopher Hamaker, Portland, OR (US); Walter Schoenleber, Mintraching (DE)

Correspondence Address: APPLIED MATERIALS, INC., Patent Department, M/S 2061, P.O. Box 450 A, Santa Clara, CA, 95052, US

(73) Assignee: Applied Materials, Inc.

(21) Appl. No.: 10/435,114

(22) Filed: May 9, 2003

(51) Int. Cl. H01L 21/302; H01L 21/461

(52) U.S. Cl. 438/708

(57) ABSTRACT

An apparatus for etching a metal-containing material of a lithographic mask has a chamber with a support for supporting the mask inside the chamber. Over the metal-containing material, the mask comprises a resist layer having features with sidewalls. A gas distributor, gas energizer, and gas exhaust are provided. A controller is provided that is adapted to control one or more of the gas distributor, gas energizer, and gas exhaust to (i) deposit a sacrificial coating on the sidewalls of the features in the resist layer, and (ii) etch the metal-containing material of the mask. Coincidental etching of the sidewalls of the features in the resist layer overlying the metal-containing material is reduced by the sacrificial coating formed thereon.

### BACKGROUND

Embodiments of the present invention relate to the etching of a lithographic mask in an energized gas.

In the fabrication of a patterned lithographic mask that is used to fabricate integrated circuits, printed circuits (PCB), displays, and other patterned boards, a patterned metal-containing material is formed on a radiation permeable plate. The lithographic mask is used to transfer a pattern into a final substrate product, such as a semiconductor wafer or dielectric. A typical process for fabricating a lithographic mask may include, for example, (i) providing metal-containing material on a radiation permeable plate, (ii) forming a resist layer on the metal-containing material to create a blank lithographic mask, the resist layer being a photoresist, electron-beam sensitive resist, or ion-beam sensitive resist, (iii) selectively exposing the blank lithographic mask to a laser beam, electron beam, or ion beam, (iv) developing the exposed material to reveal a pattern of resist features, (v) etching the revealed portions of the metal-containing material between the resist features to transfer the pattern captured in the resist features into the metal-containing material, and (vi) stripping remaining resist layer from the lithographic mask.

Lithographic masks having a high surface density of closely spaced features are used to make faster or smaller integrated circuits and PCBs. However, as the mask features become more closely spaced, it becomes more desirable to control the critical dimensions of the mask features to control the electrical properties of the features etched in the final substrate product created using the lithographic mask. For example, it is especially desirable to maintain consistent and uniform critical dimensions for electrical interconnect lines and vias of integrated circuits because their electrical resistance is proportional to their cross-sectional area. It is also desirable for the cross-sectional profile of the etched features to be consistent across the substrate, and not to vary with the distance between, or the aspect ratio of, the etched features.

While etching the lithographic mask to transfer a pattern in the resist layer to the underlying metal-containing material, undesirable lateral etching of the sidewalls of the resist features often occurs, which is referred to as lateral dimension shrinking. For example, when etchant gas comprising chlorine-containing gas and oxygen-containing gas is used to the etch metal-containing material, the oxygen-containing etchant gas also etches into the sidewalls of the overlying resist features. The thinner overlying resist feature results in excessive lateral etching into the sidewalls of the mask features being etched in the metal-containing material. As a result, the mask features have critical dimensions that are thinner than those originally intended. When this mask is used to define electrical interconnect lines in an integrated circuit substrate, the lines are etched with widths that are thinner than intended, and consequently, have higher electrical resistances, which is undesirable.

Thus it is desirable to etch features on a mask substrate without excessively etching the sidewalls of resist features of the mask. It is further desirable to etch the features with consistent and reproducible shapes and critical dimensions. It is also desirable to have production worthy etch rates to provide mask processing efficiency.

### SUMMARY

In a lithographic mask fabrication method, a mask comprising a radiation permeable plate and an overlying metal-containing material is selected. A pattern of resist features is formed on the metal-containing material by forming a resist layer on the metal-containing material, selectively exposing the resist layer to optical radiation, and developing the resist layer to form a pattern of resist features that have sidewalls and dimensions between the sidewalls. The metal-containing material is then placed in a process zone. In a sacrificial coating deposition stage, a silicon-containing gas is provided in the process zone and energized to deposit a silicon-containing sacrificial coating on the sidewalls of the resist features. In a metal etching stage, an etchant gas is provided in the process zone to etch the metal-containing material and thereby expose portions of the radiation permeable plate. The sacrificial coating on the sidewalls of the resist features impedes etching of the sidewalls and thereby maintains the dimensions of the resist features.

In another version of the fabrication method, in the sacrificial coating deposition stage, a deposition gas comprising CH₃Cl is provided in the process zone to deposit a sacrificial coating comprising a carbon polymer on the sidewalls of the resist feature. The deposition gas can also include less than about 10% of CCl₄.

A corresponding etching apparatus comprises a chamber having a support to support a mask inside the chamber. The mask has resist features with sidewalls. A gas distributor is provided to pass a gas in the chamber, a gas energizer to energize the gas, and a gas exhaust to exhaust the gas. A controller is adapted to control the gas distributor, gas energizer, and gas exhaust to (i) in a sacrificial coating deposition stage, provide a deposition gas comprising CH₃Cl in the chamber to deposit a sacrificial coating on the sidewalls of the resist features of the mask, and (ii) in a metal etching stage, provide an etchant gas in the chamber to etch the metal-containing material. The sacrificial coating on the sidewalls of the resist features impedes etching of the sidewalls and thereby maintains the dimensions of the resist features during etching of the metal-containing material.

In another version, the controller of the mask etching apparatus provides a silicon-containing deposition gas in the chamber during the sacrificial coating deposition stage, to deposit a silicon-containing sacrificial coating on the sidewalls of the features in the resist layer of the mask.

### DRAWINGS

These features, aspects, and advantages of the present invention will become better understood with regard to the following description, appended claims, and accompanying drawings which illustrate examples of the invention. However, it is to be understood that each of the features can be used in the invention in general, not merely in the context of the particular drawings, and the invention includes any combination of these features, where:

FIG. 1 is a cross-sectional side view of a lithographic mask before development of the resist layer;

FIG. 2 is a cross-sectional side view of the lithographic mask of FIG. 1 during the development of the resist layer;

FIG. 3 is a cross-sectional side view of the lithographic mask of FIG. 2 after formation of a sacrificial coating on the resist layer; and

FIG. 4 is a cross-sectional side view of the lithographic mask of FIG. 3 after a metal etching stage;

FIG. 5 is a mask processing apparatus for processing a lithographic mask; and

FIG. 6 is a schematic diagram of the controller in FIG. 5.

### DESCRIPTION

A lithographic mask 10 is processed in a process zone 108 to form etched features 34 in the mask 10. For example, it may be desirable to etch a metal-containing material of the mask 10 to form the features 34 therein. In one embodiment, the mask 10 comprises a radiation permeable plate 20 underneath the metal-containing material 15. The metal-containing material 15 may comprise chromium, but the metal-containing material 15 may alternatively or additionally comprise other materials, such as iron oxide or molybdenum. The radiation permeable plate 20 may comprise quartz, glass, sapphire, or another translucent material.

A typical process sequence for forming the etched features 34 comprises the steps of (1) depositing the metal-containing material 15 on the radiation permeable plate 20, (2) forming an overlying resist layer 35 of resist material that is capable of capturing a pattern to be transferred into the metal-containing material 15, and is typically composed of photoresist, electron sensitive resist, or ion-beam sensitive resist, (3) selectively exposing the resist layer 35 to optical radiation according to a pattern, (4) developing the resist layer 35 to form developed features 32 according to the pattern, (5) in an etching stage, providing an energized gas composition to transfer the pattern formed in the resist layer 35 into the metal-containing material by etching the metal-containing material 15 of the mask 10 through exposed spaces 36 in the resist layer 35, thereby extending the developed resist features 32 below the resist layer 35 and into the metal-containing material 15 to form etched metal features 34, and (6) ashing with oxygen-containing plasma to remove (or strip) any remaining resist (if any is present) and to passivate the etched metal features 34 by removing residual etching species to prevent corrosion. Light-sensitive photoresists that may also be at least partially electron sensitive include Shipley UV6, Clariant DX-1100, and FEP-170. Electron sensitive resists include ZEP-7000 among others. Ion-beam sensitive resists include Tokyo-Ohka IP3600, Tokyo-Ohka IP3700, Tokyo-Ohka IP3500, and Tokyo-Ohka M100. The present invention relates to the etching stage in this sequence in which the pattern of lines or other features captured in the resist layer 35 is transferred into the metal-containing material 15 by a plasma etch process (sometimes referred to as reactive ion etching or RIE).

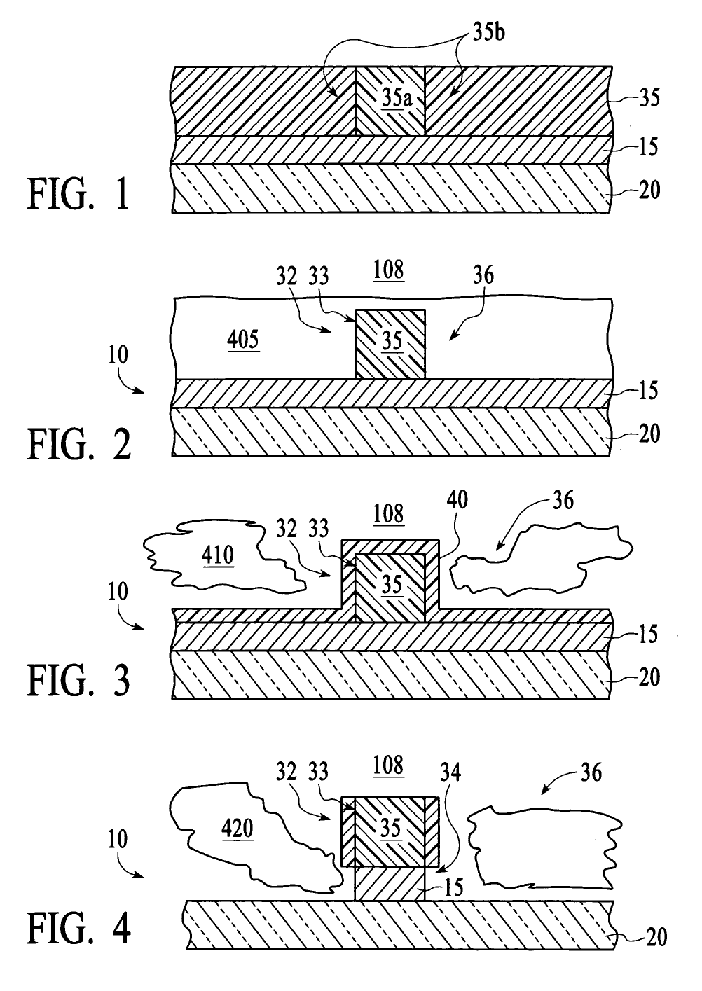

The pattern of resist features 32 is formed on the metal-containing material 15 by first forming a resist layer 35 on the metal-containing material 15. The resist layer 35 on the mask 10 is selectively exposed to optical radiation to form individual regions 35a,b that are polymerized and unpolymerized, respectively. The resist layer 35 is then developed to form a pattern of resist features 32 that have sidewalls 33 and exposed spaces 36 with dimensions between the sidewalls 33. The development process either (i) removes the regions that were exposed to the optical radiation (for a “positive”-type resist layer), or (ii) removes the regions that were not exposed to the optical radiation (for a “negative”-type resist layer), to form a pattern of resist features 32 having sidewalls 33. FIG. 1 illustrates the mask 10 before the development stage, and FIG. 2 illustrates the mask 10 during the development stage when the mask 10 comprises a patterned resist layer 35 with developed features 32. In one embodiment, the development stage comprises wet development, in which the mask 10 is placed in a liquid bath 405 to remove the selected portions of the mask 10. Alternatively, the development stage may comprise dry development, in which the resist layer 35 is patterned using a gas.

Next, the metal-containing material 15 is etched according to the pattern in the resist layer 35. In operation, the mask 10 is placed in a process zone 108. In a sacrificial coating deposition stage, as illustrated in FIG. 3, a deposition gas 410 is introduced into the process zone 108 and energized to deposit a sacrificial coating 40 on the sidewalls of the features 32 of the resist layer 35. The sacrificial coating 40 may have a thickness of from about 10 to about 50 nanometers, such as from about 20 to about 35 nanometers. The sacrificial coating 40 covers the features 32 of the resist layer 35 such that the resist layer 35 substantially preserves its lateral dimensions while it is etched in the etching stage. The preservation of the resist layer's lateral dimensions, such as a width of the features, allows for the preservation of the same lateral dimensions of the final etched features. The sacrificial coating 40 produced by the deposition gas 410 maintains consistent dimensions of the exposed spaces 36, such as consistent critical dimensions (CD), substantially absent sidewall etching.

In one version, the deposition gas 410 comprises silicon, such as in the form of a silicon-containing compound or elemental silicon. A silicon-containing deposition gas 410 is provided in the process zone 108 and the gas is energized to deposit a silicon-containing sacrificial coating 40 on the sidewalls 33 of the resist features 32. In one embodiment, the deposition gas 410 comprises SiF₄, such as to deposit a sacrificial coating 40 on the mask 10 that comprises SiO₂. The silicon-containing sacrificial coating 40 may have a thickness of from about 3 to about 25 nm, such as from about 5 to about 15 nm.

In another version, the deposition gas 410 additionally or alternatively comprises a compound having the general formula CₐCl_{b} or CₐX_{b}Cl_{c}, where ‘X’ is hydrogen or nitrogen, and ‘a’, ‘b’, and ‘c’ are whole numbers. For example, suitable gaseous compounds for the sacrificial deposition gas 410 may include CH₃Cl or CCl₄. These compounds have been found to promote the formation of an advantageous sacrificial coating 40 comprising a sufficient amount of carbon.

The deposition gases 410 described herein have been discovered to be especially advantageous in particular circumstances. For example, the inhibition of the etching of the sidewalls 33 of the features 32 is particularly improved for features 32 having small opening sizes or high aspect ratios. When high aspect ratio features 32 are etched without the sacrificial coating 40 from the prior deposition gas 410, the etching of the resist layer 35 may provide insufficient polymer to extend the sacrificial coating 40 to the lower regions of the feature 32, and thus not inhibit the sidewall etching of those regions. By providing a deposition gas 410 described herein, more species capable of forming a sacrificial coating 40 are provided to the sidewalls 33 of the resist features 32 to inhibit the etching of the sidewalls 33. In one embodiment, the sacrificial coating 40 is deposited on the sidewalls 33 of the resist features 32 in a sufficient thickness that the width of the etched features 32 after the metal etching stage is within an average deviation of less than about 5% from the width of the overlying resist features 32 before the metal etching stage. For example, this average deviation may be less than about 20 nm.

In one embodiment, the deposition gas 410 is selected to contain less than about 10% of carbon tetrachloride (CCl₄). CCl₄ is physiologically harmful, as a known carcinogen, as well as environmentally harmful. For these reasons, it is currently banned for use in the United States and some European countries. Therefore, a halocarbon deposition gas 410 that is substantially absent carbon tetrachloride may be desirable.

Typically, there is a preliminary etch step that occurs after depositing the silicon-containing sacrificial coating 40, but before etching the metal-containing material 15, in which the portion of the silicon-containing sacrificial coating 40 that covers the metal-containing material 15 is etched. For example, a fluorine-containing etchant gas, such as one that contains CF₄, CHF₃, or sulfur hexafluoride, can be used. These fluorine-containing etchant gases may have a better ability to etch the silicon-containing sacrificial coating 40 than chlorine-containing etchant gases.

In a metal etching stage that is executed after the sacrificial coating deposition stage, an etchant gas is provided in the process zone 108 to etch the metal-containing material and thereby expose portions of the radiation permeable plate 20. The mask 10 can be safely etched by an etchant gas 420 that reacts with the metal-containing material 15 of the mask 10 to form volatile compounds and thereby etch the metal-containing material 15, as illustrated in FIG. 4. The sacrificial coating 40 on the sidewalls 33 of the resist features 32 impedes etching of the sidewalls 33 and thereby maintains the dimensions of the resist features 32.

The etchant gas 420 is a composition typically comprising halogen-containing gases that when energized react with and etch the metal-containing material 15. For etching a chromium or aluminum metal-containing material 15, the etchant gas 420 may comprise chlorine species and oxygen species, such as including Cl₂ and O₂, HCl, BCl₃, or Cl₂. The etchant gas 420 may further comprise helium or another substantially inert gas. For etching tungsten or tungsten alloys and compounds, fluorine-containing gases, such as SF₆, NF₃, or F₂, and mixtures thereof, may be used. Alloys or compounds that contain copper or titanium can be etched with either chlorine or fluorine-containing gases. Although the invention is illustrated by particular compositions of halogen gases, it should be understood that the present invention should not be limited to the halogen gases described herein.

The etchant gas 420 can be chosen to have a desirable etch selectivity ratio, which is the ratio of the etch rate at which the etchant gas 420 etches the metal-containing material 15 to the etch rate at which the gas 420 etches the resist layer 35. For example, an etchant gas 420 having an etch selectivity ratio of at least about 7:1 may be selected, or even more preferably an etchant gas 420 having an etch selectivity ratio of at least about 10:1.

A sufficient electric potential bias is applied to the mask 10 in relation to the plasma that the etchant gas 420 anisotropically etches the mask 10. The resulting electric field above the mask 10 causes the ions of the etchant gas plasma to have a mean downward velocity, preferentially etching downward and reducing lateral etching into the resist features 32. Although the sacrificial coating 40 may be deposited substantially uniformly along the horizontal faces and vertical sidewalls 33 of the resist features 32, the anisotropic etching is a preferentially downwardly-directed etching into the metal-containing material 15. The portion of the sacrificial coating 40 on the vertical sidewalls 33 of the resist features 32 is etched more slowly than on the horizontal faces on the resist features 32 above the metal-containing material 15. Even as etching progresses through the metal-containing material 15, the sacrificial coating 40 continues to protect the vertical sidewalls 33 of the resist features 32 and thereby maintain the lateral dimensions of the resist features 32. In contrast, the vertical height of the resist features 32 may be slightly reduced. A sufficient electric potential bias to produce desirably anisotropic etching may be at least about 60 Volts, such as at least about 100 Volts.

In an alternative version, the sacrificial coating 40 is anisotropically deposited on the mask 10 to be thinner on the metal-containing material 15 than on the sidewalls 33 of the protruding resist features 32 to allow simultaneous etching of the metal-containing material 15 and the part of the sacrificial coating 40 on the sidewalls 33. The sacrificial coating 40 overlying the metal-containing material 15 can be etched through to reveal and etch the metal-containing material 15, while the sacrificial coating 40 overlying sidewalls 33 of the resist features 32 remains to prevent etching of the resist feature sidewalls 33. For example, the sacrificial coating 40 may have a ratio of thickness on the metal-containing material 15 to thickness on the resist features 32 of less than about one-tenth. This anisotropic deposition of the sacrificial coating 40 can be accomplished by selecting a deposition gas 410 that preferentially deposits the sacrificial material on the resist layer 35 rather than on the metal-containing material 15.

The deposition gas 410 or etchant gas 420 may further comprise one or more additive gases. For example, the additive gas may comprise a non-reactive gas to provide a good flow of the deposition or etchant gas 410, 420 to the mask 10. The additive gas may comprise, for example, He, Ar, or N₂. The volumetric flow rate of the non-reactive gas may be selected according to the desired flow rate of the deposition or etchant gas 410, 420 to set a net volumetric flow rate. For example, the non-reactive gas may be provided at a volumetric flow rate equivalent to a flow rate of less than about 50 sccm for a process zone volume of about 25 liters.

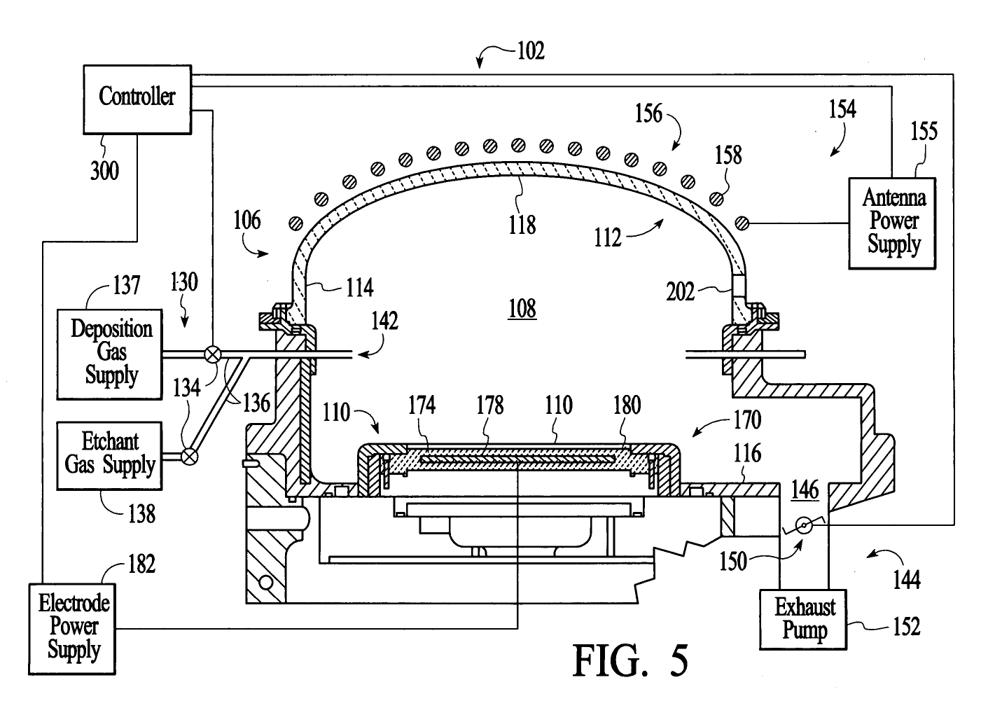

The mask 10 is processed in a process chamber 106 of a mask processing apparatus 102, a particular embodiment of which is shown in FIG. 5, which is provided only to illustrate the invention and should not be used to limit the scope of the invention. Other process chambers 106 that can be used to practice the present process include parallel plate reactors, various inductively coupled plasma reactors, electron cyclotron resonance reactors, and helicon wave reactors. The chamber 106 may comprise, for example, a mask etch chamber similar to a decoupled plasma source (DPS) chamber, commercially available from Applied Materials Inc., Santa Clara, Calif. The particular embodiment of the chamber 106 shown herein is suitable for processing lithographic masks 10.

Generally, the chamber 106 is fabricated from metal or ceramic materials. Metals commonly used to fabricate the chamber 106 include aluminum, anodized aluminum, “HAYNES 242,” “Al-6061,” “SS 304,” “SS 316,” and INCONEL, of which anodized aluminum may be preferred. In the embodiment shown, the chamber 106 comprises sidewalls 114, a bottom wall 116, and a ceiling 118. The ceiling 118 may comprise substantially flat, domed, or multi-radius shaped portion. The chamber 106 typically encloses a process zone with a volume of at least about 10 liters. The deposition gas 410 may reduce erosion of vertical surfaces of the chamber 106, such as for example the surfaces of the chamber sidewalls 114, by forming a protective layer (not shown) on the chamber surfaces that protects the underlying surfaces from the erosive components of the etchant gas 420.

In operation, the deposition and etchant gases 410, 420 are introduced in different time stages into a process zone 108 of the chamber 106 through a gas distributor 130 that includes a deposition gas supply 137, etchant gas supply 138, conduits 136 having flow control valves 134 to convey the gases 410, 420 into the chamber 106, and gas outlets 142 around a periphery of the mask 10 held on a support 110 inside the chamber 106. Alternatively to the configuration shown in FIG. 5, the deposition or etchant gas 410, 420 may be introduced through a showerhead (not shown) mounted on the ceiling 118 of the chamber 106.

The deposition or etchant gas 410, 420 is energized to process the mask 10 by a gas energizer 154 that couples energy to the gas 410, 420 in the process zone 108 of the chamber 106 (as shown) or in a remote zone upstream from the chamber 106 (not shown). In one version, the gas energizer 154 comprises an antenna 156 having one or more inductor coils 158, which may have a circular symmetry about the center of the chamber 106. Typically, the antenna 156 comprises solenoids, each solenoid having from 1 to about 20 turns. A suitable arrangement of solenoids is selected to provide a strong inductive flux linkage and coupling to the gas 410, 420. When the antenna 156 is positioned near the ceiling 118 of the chamber 106, the adjacent portion of the ceiling 118 may be made from a dielectric material, such as silicon dioxide, that is radiation permeable to electromagnetic RF fields. An antenna power supply 155 provides, for example, RF power to the antenna 156 at a frequency of typically about 50 kHz to about 60 MHz, and more typically about 13.56 MHz; and at a power level of from about 100 to about 5000 Watts. An RF match network (not shown) may also be provided. Alternatively or additionally, the gas energizer 154 may comprise a microwave gas activator (not shown).

The gas energizer 154 may additionally or alternatively comprise process electrodes (not shown) that are used to energize the process gas. Typically, the process electrodes include one electrode (not shown) in a wall, such as a sidewall 114 or ceiling 118 of the chamber 106, that is capacitively coupled to another electrode, such as an electrode in the support 110 below the mask 10. Generally, the electrodes are electrically biased relative to one another by an electrode voltage supply (not shown) that includes an AC voltage supply for providing an RF bias voltage.

Spent process gases and processing byproducts are exhausted from the chamber 106 through an exhaust system 144 that includes a pumping channel 146 to receive spent process gas, a throttle valve 150 to control the pressure of the process gas 410, 420 in the chamber 106, and one or more exhaust pumps 152 to drive the spent process gas out of the exhaust system 144. The exhaust system 144 may also contain a system for abating undesirable gases in the exhaust.

The support 110 may comprise an electrostatic chuck 170, which includes a dielectric body 174 that at least partially covers an electrode 178 and has a mask receiving surface 180. The electrode 178 may also serve as one of the process electrodes discussed above. The electrode 178 may also be capable of generating an electric field for electrically. biasing the mask 10 and electrostatically holding the mask 10 to the support 110 or electrostatic chuck 170. A DC power supply 182 provides the chucking voltage to the electrode 178.

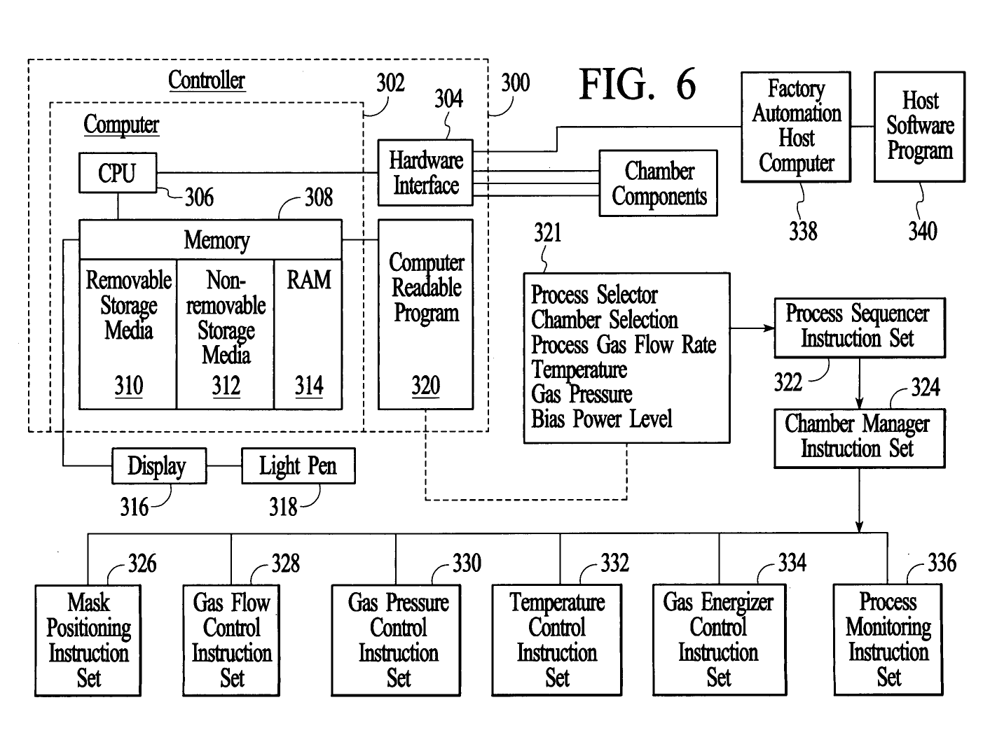

The apparatus 102 may comprise a controller 300 that controls the chamber 106 via a hardware interface 304. The controller 300 comprises a computer 302, which may include a central processing unit (CPU) 306, such as for example a 68040 microprocessor, commercially available from Synergy Microsystems, California, or a Pentium Processor commercially available from Intel Corporation, Santa Clara, Calif., that is coupled to a memory 308 and peripheral computer components, as shown in FIG. 6. The memory 308 may comprise a removable storage medium 310, such as for example a CD or floppy drive, a non-removable storage medium 312, such as for example a hard drive 313, and random access memory 314. The controller 300 may further comprise a plurality of interface cards including, for example, analog and digital input and output boards, interface boards, and motor controller boards. The interface between an operator and the controller 300 can be, for example, via a display 316 and a light pen 318. The light pen 318 detects light emitted by the display 316 with a light sensor in the tip of the light pen 318. To select a particular screen or function, the operator touches a designated area of a screen on the display 316 and pushes the button on the light pen 318. Typically, the area touched changes color, or a new menu is displayed, confirming communication between the user and the controller 300.

The controller 300 is adapted to control the gas distributor 130, gas energizer 154, and gas exhaust 144 to (i) deposit the sacrificial coating 40 on the mask 10 to protect the sidewalls 33 of the resist features 32, and (ii) safely etch the mask 10. The sacrificial coating 40 on the sidewalls 33 of the freshly etched resist features 32 reduces the etching of the resist sidewalls 33 during the mask etching process. As the mask 10 is sacrificially etched downwardly, the sacrificial coating 40 on the sides of the resist features 32 is etched horizontally and thus serves as a buffer to protect the underlying metal features 34 from excessive horizontal etching.

The data signals received and evaluated by the controller 300 may be sent to a factory automation host computer 338. The factory automation host computer 338 comprises a host software program 340 that evaluates data from several systems, platforms or chambers 106, and for batches of masks 10 or over an extended period of time, to identify statistical process control parameters of (i) the processes conducted on the masks 10, (ii) a property that varies in a statistical relationship across a single mask 10, or (iii) a property that varies in a statistical relationship across a batch of masks 10. The host software program 340 may also use the data for ongoing in-situ process evaluations or for the control of other process parameters. A suitable host software program comprises a WORKSTREAM™ software program available from aforementioned Applied Materials, Inc. The factory automation host computer 338 may be further adapted to provide instruction signals to (i) remove particular masks 10 from the processing sequence, such as if a mask property is inadequate or does not fall within a statistically determined range of values, or if a process parameter deviates from an acceptable range; (ii) end processing in a particular chamber 106, or (iii) adjust process conditions upon a determination of an unsuitable property of the mask 10 or an unsuitable process parameter. The factory automation host computer 338 may also provide the instruction signal at the beginning or end of processing of the mask 10 in response to evaluation of the data by the host software program 340.

In one version, the controller 300 comprises a computer-readable program 320 stored in the memory 308, for example on the non-removable storage media 312 or on the removable storage media 310. The computer readable program 320 generally comprises process control software comprising program code to operate the chamber 106 and its components, process monitoring software to monitor the processes being performed in the chamber 106, safety systems software, and other control software. For example, the process control software comprises a process selector 321 to select a process and associated parameters. The computer-readable program 320 may be written in any conventional computer-readable programming language, such as for example, assembly language, C++, Pascal, or Fortran. Suitable program code is entered into a single file, or multiple files, using a conventional text editor and stored or embodied in a computer-usable medium of the memory 308. If the entered code text is in a high level language, the code is compiled, and the resultant compiler code is then linked with an object code of precompiled library routines. To execute the linked, compiled object code, the user invokes the object code, causing the CPU 306 to read and execute the code to perform the tasks identified in the program.

A block diagram of a hierarchical control structure of a specific embodiment of a computer readable program 320 is illustrated in FIG. 6. Using a light pen interface, a user enters a process set and chamber number into the computer readable program 320 in response to menus or screens on the display 316. The computer readable program 320 includes program code to control the mask position, gas flow, gas pressure, temperature, RF power levels, and other parameters of a particular process, as well as code to monitor the chamber process. The process sets are predetermined groups of process parameters necessary to carry out specified processes. For example, the process parameters can include, without limitations, gas composition, gas flow rate, temperature, pressure, gas energizer settings such as RF or microwave power levels, magnetic field generation, heat transfer gas pressure, and wall temperature.

The process sequencer instruction set 322 comprises program code to accept a chamber type and set of process parameters from the computer readable program 321 and to control its operation. The sequencer instruction set 322 initiates execution of the process set by passing the particular process parameters to a chamber manager instruction set 324 that controls multiple processing tasks in the process chamber 106. Typically, the process chamber instruction set 324 includes a mask positioning instruction set 326, a gas flow control instruction set 328, a gas pressure control instruction set 330, a temperature control instruction set 332, a gas energizer control instruction set 334, and a process monitoring instruction set 336. The mask positioning instruction set 326 comprises program code for controlling chamber components that are used to load the mask 10 onto the support 110 and, optionally, to lift the mask 10 to a desired height in the chamber 106.

The gas flow control instruction set 328 comprises program code to control the flow rates of different constituents of the deposition or etchant gas 410, 420 by regulating the opening sizes of the flow control valves 134 to obtain the desired gas flow rates. The flow rates may be controlled to obtain, for example, desired volumetric flow ratios of the constituents of the deposition or etchant gas 410, 420. For example, the gas flow control instruction set 328 of the controller 300 can command the gas distributor 130 to first introduce a selected flow rate of deposition gas 410 into the process zone 108 of the chamber 106 to deposit a suitable sacrificial coating 40 on the mask 10, the sacrificial coating 40 having a desirable composition and sufficient thickness. The gas flow control instruction set 328 also comprises program code to set the volumetric flow rate of the etchant gas 420 to obtain the desired etching properties in the preliminary and metal etching stages.

The gas pressure control instruction set 330 comprises program code to control the pressure in the chamber 106 by controlling the open or closed position of the throttle valve 150 in the exhaust system 144 of the chamber 106. The gas energizer control instruction set 332 comprises program code for setting the RF bias power levels applied to, for example, the antenna 156. The process monitoring instruction set 334 comprises code for monitoring the process in the chamber 106. For example, the process monitoring instruction set 336 may be adapted to detect an endpoint of a process in the chamber 106.

### ILLUSTRATIVE EXAMPLE

The following prospective example illustrates an exemplary method according to the present invention. While the example demonstrates one version, the present invention may be used in other processes and for other uses as would be apparent to those of ordinary skill in the art and the invention should not be limited to the example provided herein.

In one example suitable for etching a mask 10 having a chromium layer 15 underneath the resist layer 35, a preliminary etch stage is carried out in which a first etchant gas comprising Cl₂ is introduced into the chamber 106. The etchant gas etches the exposed (for positive-type resist) or unexposed (for negative-type resist) regions of the mask 10 and reveals open areas at their locations.

A deposition gas 410 comprising CH₃Cl is introduced into the chamber 106 at a flow rate equivalent to from about 2 to about 100 sccm for a chamber 106 having a process volume of about 25 liters. The gas pressure in the chamber 106 is maintained at from about 5 to about 80 mTorr, and the temperature of the electrode 178 in the electrostatic chuck 170 is maintained at from about 15 to about 60° C. The deposition gas 410 deposits a polymer sacrificial coating 40 on the features 32 of the resist layer 35.

Subsequent to the sacrificial deposition step, a second etchant gas 420 is introduced into the chamber 106. The etchant gas 420 may comprise, for example, Cl₂ and O₂, having a desirable etch selectivity ratio of at least about 8:1. The etchant gas 420 is introduced at a volumetric flow rate equivalent to from about 15 to about 300 sccm, for example from about to about 200 sccm of Cl₂ and from about 5 to about 100 sccm of O₂, for the chamber 106. The etchant gas 420 etches a chromium metal-containing layer 15 underneath the resist layer 35 while preventing excessive sidewall etching of the features 32 of the resist layer 35 themselves or the portions of the chromium metal-containing layer 15 directly underneath the resist features 32. The mask 10 may be etched by the etchant gas 420 until the endpoint of the etch process is detected by an endpoint detector (not shown). Optionally, an additive gas such as N₂ may be added to one or more of the deposition or etchant gases 410, 420 at a flow rate equivalent to less than about 50 sccm for the chamber 106.

The present mask processing apparatus 102 and method is advantageous because it allows etching of metal features 34 of a mask 10 without excessively etching the sidewalls 33 of the resist features 32 that are above the metal features 34 and define the shapes of the metal features 34. This maintains consistent and reproducible shapes and dimensions of the etched features Although this invention has been described in considerable detail with regard to the preferred version thereof, other versions are possible. For example, the plasma can be formed using a microwave plasma source, and the second etchant gas can be used to etch other materials, such as dielectric or semiconductor materials, while preventing excessive sidewall etching of the resist features 32 of the mask 10. Thus, the appended claims should not be limited to the description of the preferred versions contained herein.

What is claimed is:

1. A lithographic mask fabrication method comprising:
(a) selecting a mask comprising a radiation permeable plate and an overlying metal-containing material;
(b) forming a pattern of resist features on the metal-containing material by:
(i) forming a resist layer on the metal-containing material;
(ii) selectively exposing the resist layer to optical radiation; and
(iii) developing the resist layer to form a pattern of resist features that have sidewalls and dimensions between the sidewalls; and
(c) etching the metal-containing material by:
(i) placing the mask in a process zone;
(ii) in a sacrificial coating deposition stage, providing a silicon-containing gas in the process zone and energizing the gas to deposit a silicon-containing sacrificial coating on the sidewalls of the resist features; and
(iii) in a metal etching stage, providing an etchant gas in the process zone to etch the metal-containing material and thereby expose portions of the radiation permeable plate, and
whereby the sacrificial coating on the sidewalls of the resist features impedes etching of the sidewalls and thereby maintains the dimensions of the resist features.

2. A method according to claim 1 wherein (c)(ii) comprises providing a silicon-containing gas comprising SiF₄.

3. A method according to claim 1 wherein (c)(ii) comprising energizing the gas to deposit a sacrificial coating comprising SiO₂.

4. A method according to claim 1 wherein (c)(ii) comprises depositing the silicon-containing sacrificial coating in a sufficient thickness that a width of features in the metal-containing material after the metal etching stage is within an average deviation of less than about 5% from the width of the resist features before the metal etching stage.

5. A method according to claim 1 wherein (c)(ii) comprises depositing a silicon-containing sacrificial coating having a thickness of from about 5 to about 50 nanometers.

6. A method according to claim 1 wherein (c)(iii) comprises providing an etchant gas comprising chlorine species and oxygen species.

7. A lithographic mask fabrication method comprising:
(a) selecting a mask comprising a radiation permeable plate and an overlying metal-containing material;
(b) forming a pattern of resist features on the metal-containing material by:
(i) forming a resist layer on the metal-containing material;
(ii) selectively exposing the resist layer to optical radiation; and
(iii) developing the resist layer to form a pattern of resist features having sidewalls and dimensions between the sidewalls; and
(c) etching the metal-containing material by:
(i) placing the mask in a process zone;
(ii) in a sacrificial coating deposition stage, providing a deposition gas in the process zone to deposit a sacrificial coating on the sidewalls of the resist features, the deposition gas comprising CH₃Cl; and
(iii) in a metal etching stage, providing an etchant gas to etch the metal-containing material to expose portions of the radiation permeable plate,
whereby the sacrificial coating on the sidewalls of the resist features impedes etching of the sidewalls and thereby maintains the dimensions of the resist features.

8. A method according to claim 7 wherein (c)(ii) comprises providing a deposition gas containing less than about 10% of CCl₄.

9. A method according to claim 7 wherein (c)(iii) comprises providing an etchant gas comprising chlorine species and oxygen species.

10. An apparatus for etching a metal-containing material of a lithographic mask without excessive etching of the sidewalls of features of a resist layer overlying the metal-containing material, the apparatus comprising:
(a) a chamber having a support to support a mask inside the chamber, the mask comprising a resist layer having features with sidewalls;
(b) a gas distributor to provide a gas in the chamber;
(c) a gas energizer to energize the gas;
(d) a gas exhaust to exhaust the gas; and
(e) a controller adapted to control the gas distributor, gas energizer, and gas exhaust to:
(i) in a sacrificial coating deposition stage, provide a deposition gas in the chamber to deposit a sacrificial coating on the sidewalls of the features in the resist layer of the mask, the deposition gas comprising CH₃Cl, and
(ii) in a metal etching stage, provide an etchant gas in the chamber to etch the metal-containing material,
whereby the sacrificial coating on the sidewalls of the resist features impedes etching of the sidewalls and thereby maintains the dimensions of the resist features during etching of the metal-containing material.

11. An apparatus according to claim 10 wherein the controller is adapted to control the gas distributor to provide a deposition gas containing less than about 10% of CCl₄.

12. An apparatus according to claim 10 wherein the gas distributor is adapted to provide an etchant gas comprising chlorine species and oxygen species in the chamber.

13. An apparatus for etching a metal-containing material of a lithographic mask without excessive etching of the sidewalls of features of a resist layer overlying the metal-containing material, the apparatus comprising:
(a) a chamber having a support to support a mask inside the chamber, the mask comprising a resist layer having features with sidewalls;
(b) a gas distributor to provide a gas in the chamber;
(c) a gas energizer to energize the gas;
(d) a gas exhaust to exhaust the gas; and
(e) a controller adapted to control the gas distributor, gas energizer, and gas exhaust to:
(i) in a sacrificial coating deposition stage, provide a silicon-containing deposition gas in the chamber to deposit a silicon-containing sacrificial coating on the sidewalls of the features in the resist layer of the mask, and
(ii) in a metal etching stage, provide an etchant gas in the chamber to etch the metal-containing material on the mask,
whereby the sacrificial coating on the sidewalls of the resist features impedes etching of the sidewalls and thereby maintains the dimensions of the resist features during etching of the metal-containing material.

14. An apparatus according to claim 13 wherein the controller is adapted to control the gas distributor, gas energizer, and gas exhaust in (e)(i) to provide a silicon-containing gas comprising SiF₄ in the chamber.

15. An apparatus according to claim 13 wherein the controller is adapted to control the gas distributor, gas energizer, and gas exhaust in (e)(i) to energize the gas to deposit a sacrificial coating comprising SiO₂ on the sidewalls of the features in the resist layer of the mask.

16. An apparatus according to claim 13 wherein the controller is adapted to control the gas distributor, gas energizer, and gas exhaust in (e)(i) to deposit the silicon-containing sacrificial coating in a sufficient thickness that a width of features in the metal-containing material after the metal etching stage is within an average deviation of less than about 5% from the width of the resist features before the metal etching stage.

17. An apparatus according to claim 13 wherein the controller is adapted to control the gas distributor, gas energizer, and gas exhaust in (e)(i) to deposit a silicon-containing sacrificial coating having a thickness of from about 5 to about 50 nanometers.

18. An apparatus according to claim 13 wherein the gas distributor is adapted to provide an etchant gas comprising chlorine species and oxygen species in the chamber.
